(19) United States
(12) Patent Application Publication
(10) Pub. No.: US 2003/0010750 A1
(43) Pub. Date: Jan. 16, 2003

(54) Method for determining the endpoint of etch process steps

(76) Inventors: Joseph Louis Petrucci, New Milford, CT (US); Thomas Morgenstern, Dresden (DE)

Correspondence Address: LERNER AND GREENBERG, P.A., Post Office Box 2480, Hollywood, FL, 33022-2480, US

(21) Appl. No.: 10/113,344

(22) Filed: Apr. 1, 2002

Related U.S. Application Data
(63) Continuation of application No. PCT/EP00/09518, filed on Sep. 28, 2000.

(30) Foreign Application Priority Data
Sep. 30, 1999 (EP) 99119443.2

(51) Int. Cl. C23F 1/00; C03C 15/00; H01L 21/306

(52) U.S. Cl. 216/59; 216/60

(57) ABSTRACT

A method for determining the endpoint of an etching process step performed on a wafer by using an optical or an interferometric endpoint determination system. According to the new method, a measuring step is introduced to the wafer alignment step, and this measuring step determines the thickness of the PAD nitride on the top of the wafer. The film thickness data are added to the target of the endpoint algorithm and the etch step is stopped if the target depth plus the value of the measurement is reached.

### CROSS-REFERENCE TO RELATED APPLICATION

This application is a continuation of copending International Application No. PCT/EP00/09518, filed Sep. 28, 2000, which designated the United States.

### BACKGROUND OF THE INVENTION

Field of the Invention

The invention is directed to a method for determining the endpoint of an etching step, for example, an etching step for etching a recess in a wafer in which an optical or an interferometric endpoint determination system is used with a vacuum etch chamber during the etching steps that are carried out.

Several etch process steps such as the recess 2 and recess 3 steps are carried out within a vacuum chamber or a chamber with a low internal pressure. The vacuum chamber is normally provided with a plasma source for ionizing an etching gas that is introduced in the chamber. At front end of an etching step, it is necessary to provide a wafer with an etch mask such as PAD nitride.

Many product types incorporate process steps that require blind etches that stop within a film layer. Such processes include Recess Etches and Shallow Trench Isolation. The use of an endpoint measuring system has improved the accuracy of the target depths that can be achieved. The chamber is further provided with a dome to separate the vacuum chamber from the environment. For this measuring system, this dome has a top end with a window for determining the endpoint of the etching process. Such an endpoint determining system is an optical system that monitors the etch process and incorporates an interferometric measuring system that determines the depth of the etched recesses or trenches in a semiconductor wafer that is positioned in the chamber on top of a base.

The target depths are referenced from the silicon surface, which is usually below a masking layer (PAD nitride). The problem is that the masking layer can vary from lot to lot or from wafer to wafer. The problem regarding the endpoint determination system is that Interferometric Endpoint measuring systems (IEP) are able to determine the depth of a hole or a trench, but the depth that is determined is not the target depth. The measured depth depends on the thickness of the masking layer on the top surface of the silicon. Therefore the depth of e.g. recess 2 and recess 3 varies depending on the thickness of the masking layer.

For this reason a film measurement step is required to obtain the necessary offset required to setup the IEP. This number is either the measurement of one wafer or the average of several wafers. The current endpoint systems allow for only one input per lot.

### SUMMARY OF THE INVENTION

It is accordingly an object of the invention to provide a method for determining an endpoint of an etching step that is performed to etch a recess, which method overcomes the above-mentioned disadvantages of the prior art methods of this general type.

In particular, it is an object of the invention to provide a method for determining an endpoint of an etching step that is performed to etch a recess, which method eliminates the influence of different thickness of the masking layer.

With the foregoing and other objects in view there is provided, in accordance with the invention, a method for determining an endpoint of an etching step that is performed to etch a recess. The method includes steps of: providing a wafer having a substrate and a mask formed by a mask layer provided on top of the substrate; performing a wafer alignment step to align the wafer in a vacuum etch chamber; measuring a thickness of the mask layer on top of the substrate to determine a thickness value representing a thickness of the mask layer; performing the step of measuring the thickness of the mask layer while performing the wafer alignment step; forwarding the thickness value to an interferometric endpoint determination system for performing an endpoint algorithm; adding the thickness value to a target depth value of the endpoint algorithm; performing the etching step to etch the recess into the substrate relative to the mask formed by the mask layer; during the etching step, measuring the depth of the recess to obtain a depth value representing the depth of the recess; and stopping the etching step when the depth value reaches a sum of the target depth value and the thickness value.

In accordance with an added feature of the invention, a laser measurement system is used to perform the step of measuring the thickness of the mask layer.

In accordance with an additional feature of the invention, the laser measurement system performs ellipsometry.

In accordance with another feature of the invention, the step of measuring the thickness of the mask layer is performed by directing a laser beam of a laser measuring system towards a center of the wafer.

In accordance with a further feature of the invention, a nitride layer is provided as the mask layer.

Another object of the present invention is to minimize the necessary tool adaption.

A further object of the present invention is to provide a method that can be used on all etches that must stop in the film being etched and not at an interface.

It is also an object of the invention to provide a method that can be used with 300 mm wafers and with future embodiments of wafers.

In accordance with one object of the invention, there is provided, a method for determining the endpoint of etch process steps, e.g. during recess etch steps of wafers. After the wafer is aligned, an optical endpoint determination system is used with a vacuum etch chamber while the etching steps are carried out. A measuring step is introduced to the wafer alignment step and this measuring step is used to determine the thickness of the layer on the top of the wafer. The measurement is forwarded to the endpoint determination system and is added to the target of the endpoint algorithm. The etch step is stopped if the target depth plus the value of the measurement is reached.

This new method eliminates the influences of the different thickness of the masking layer and can be used on all etches that must stop in the film being etched and not at an interface. Also the necessary tool adaption is minimized.

The measuring step is carried out preferably with a laser measurement system that is based on ellipsometry.

To minimize the time for the measuring step, the measuring step can be carried out with a laser measuring system that is preferably directed to the center of the wafer.

The layer on top of the wafer is preferably a nitride layer, e.g. a PAD nitride layer.

The new method can be used with 300 mm wafers and with future wafer embodiments.

Other features which are considered as characteristic for the invention are set forth in the appended claims.

Although the invention is illustrated and described herein as embodied in a method for determining the endpoint of an etching step, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 schematically shows the depth of an etched trench, the target depth, and the IEP target; and

FIG. 2 schematically shows an inventive method for determining the endpoint of an etching step.

### DESCRIPTION OF THE PREFERRED EMBODIMENTS

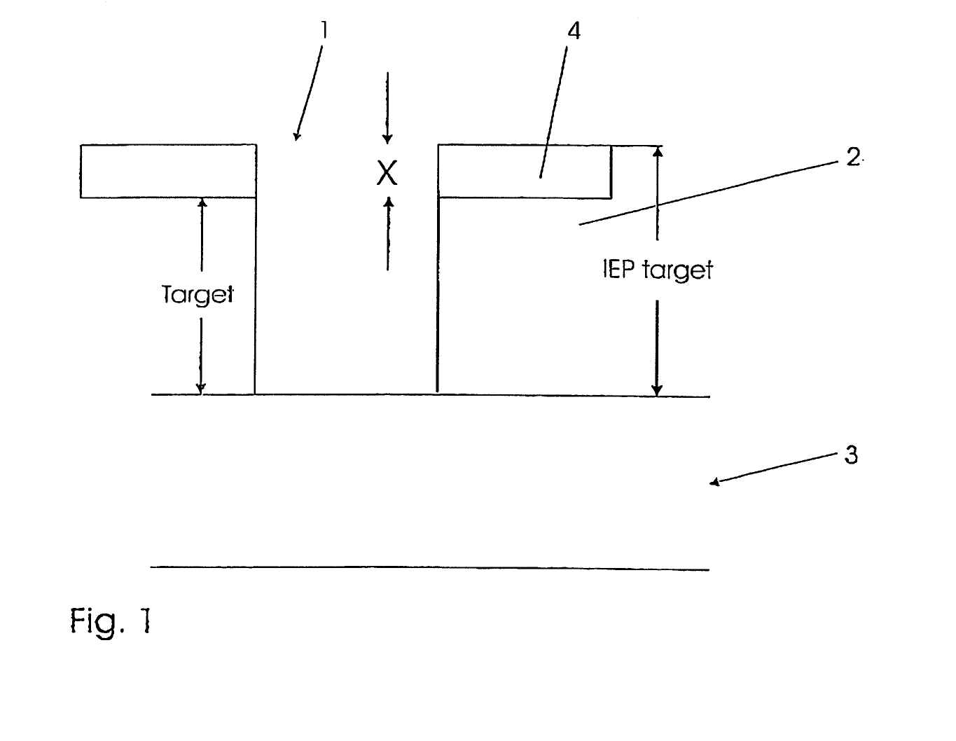

Referring now to the figures of the drawing in detail and first, particularly, to FIG. 1 thereof, there is schematically shown a poly Si layer 2 with an etched hole 1 therein, for example, a trench that has a target depth within the poly Si layer 2. This target depth is the ideal depth that is necessary to build a functional element within the wafer 3. To determine the endpoint of an etch process, an interferometric endpoint measuring system (IEP) 6, as previously discussed, is used. An IEP system is able to determine the depth of a hole 1 or a trench, however the depth that is determined is not the target depth. From FIG. 1, it is seen that the depth that is determined is a sum of the target depth and the thickness x of the PAD nitride layer 4. If the thickness of the PAD nitride layer 4 is not taken into account and the measured depth at the endpoint is erroneously equated with the target depth, then the etched hole 1 or trench will not be deep enough.

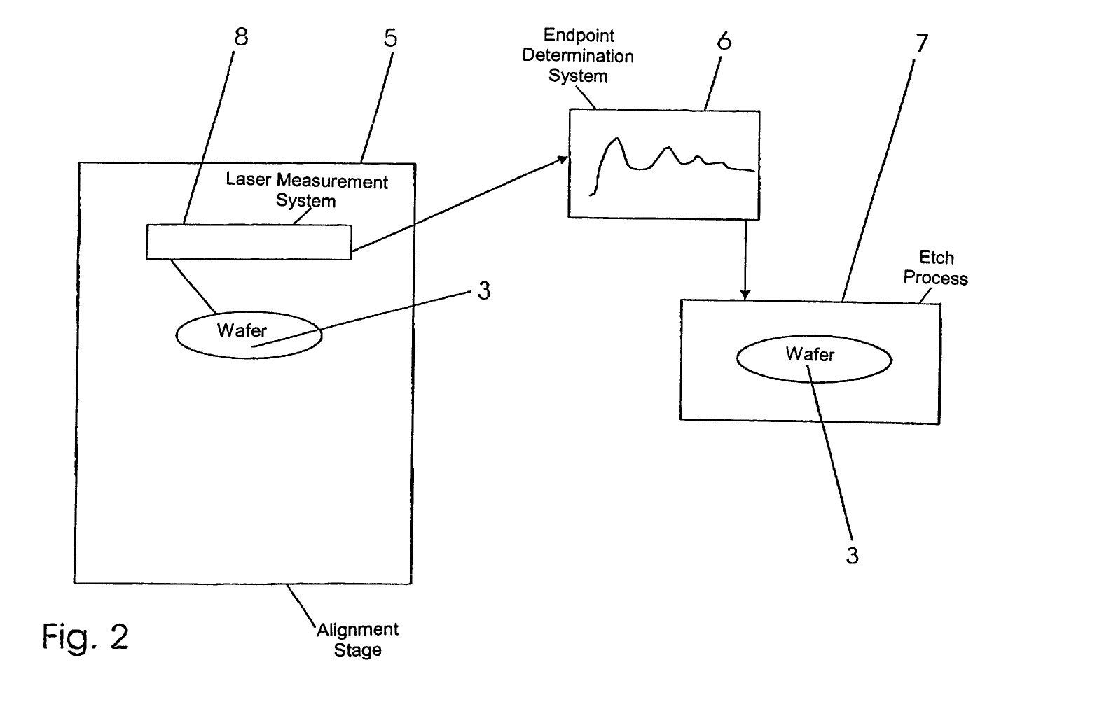

FIG. 2 illustrates an inventive method for determining the endpoint of an etching step. An additional step is carried out parallel with the alignment stage 5 at the beginning of the etch process 7. This additional step includes a thickness measuring step to determine the thickness of the PAD nitride 4 of each wafer 3 subjected to the etch process 7.

This measuring step is preferably performed with a laser measurement system 8 that is based on ellipsometry. The laser measurement system 8 first determines the thickness of the PAD nitride 4 on the top of the wafer 3, and then the measurement (film thickness data) is forwarded to the endpoint determination system 6. In this endpoint determination system (IEP), the measurement of the thickness of the PAD nitride 4 is added to the target of the endpoint algorithm. The current etch step is stopped if the target depth plus the value of the measurement is reached.

To minimize the time for measuring the thickness of the PAD nitride 4, this measuring step is carried out with the laser measurement system 8, which is directed at the center of the wafer 3.

The new method provides a wafer-to-wafer endpoint target determination by performing a PAD-nitride thickness measurement in parallel with the wafer alignment. The new method eliminates the influences of masking layers with different thickness, and can be used on all etches that must stop in the film being etched and not at an interface.

We claim:

1. A method for determining an endpoint of an etching step performed to etch a recess, which comprises:
providing a wafer having a substrate and a mask formed by a mask layer provided on top of the substrate;
performing a wafer alignment step to align the wafer in a vacuum etch chamber;
measuring a thickness of the mask layer on top of the substrate to determine a thickness value representing a thickness of the mask layer;
performing the step of measuring the thickness of the mask layer while performing the wafer alignment step;
forwarding the thickness value to an interferometric endpoint determination system for performing an endpoint algorithm;
adding the thickness value to a target depth value of the endpoint algorithm;
performing the etching step to etch the recess into the substrate relative to the mask formed by the mask layer;
during the etching step, measuring the depth of the recess to obtain a depth value representing the depth of the recess; and
stopping the etching step when the depth value reaches a sum of the target depth value and the thickness value.

2. The method according to claim 1, which comprises: using a laser measurement system to perform the step of measuring the thickness of the mask layer.

3. The method according to claim 2, wherein: the laser measurement system performs ellipsometry.

4. The method according to claim 1, which comprises:
performing the step of measuring the thickness of the mask layer by directing a laser beam of a laser measuring system towards a center of the wafer.

5. The method according to claim 1, which comprises:
providing a nitride layer as the mask layer.
